(19) United States
(12) Patent Application Publication
(10) Pub. No.: US 2021/0280397 A1
(43) Pub. Date: Sep. 9, 2021

(54) PLASMA PROCESSING APPARATUS, SEMICONDUCTIVE MEMBER, AND SEMICONDUCTIVE RING

(71) Applicant: TOKYO ELECTRON LIMITED, Tokyo (JP)

(72) Inventors: Yoichi KUROSAWA, Miyagi (JP); Shoichiro MATSUYAMA, Miyagi (JP); Yasuharu SASAKI, Miyagi (JP); Chishio KOSHIMIZU, Miyagi (JP)

(73) Assignee: TOKYO ELECTRON LIMITED, Tokyo (JP)

(21) Appl. No.: 17/191,085

(22) Filed: Mar. 3, 2021

(30) Foreign Application Priority Data
Mar. 5, 2020 (JP) 2020-037513

(51) Int. Cl. H01J 37/32; H01L 21/687; H01L 21/67

(52) U.S. Cl. CPC H01J 37/32715; H01L 21/68735; H01J 2237/0044; H01J 2237/2007; H01J 2237/334; H01L 21/67069

(57) ABSTRACT

A plasma processing apparatus includes a chamber, a stage, a semiconductive ring, a power source, at least one conductive member, and a conductive layer. The chamber has a plasma processing space. The stage is disposed in the plasma processing space and has an electrostatic chuck. The semiconductive ring is disposed on the stage so as to surround a substrate placed on the stage, the semiconductive ring having a first face. The at least one conductive member is disposed in the stage and in electrical connection with the power source. The conductive layer is disposed on the first face of the semiconductive ring and in electrical connection with the at least one conductive member.

### CROSS-REFERENCE TO RELATED APPLICATIONS

This application claims priority to Japanese Patent Application No. 2020-037513, filed on Mar. 5, 2020, the entire contents of which are incorporated herein reference.

### TECHNICAL FIELD

The present disclosure relates to a plasma processing apparatus, a semiconductive member, and an edge ring.

### BACKGROUND

Japanese Patent Application Publication No. 2018-195817 discloses a technique for performing plasma processing by applying a voltage to a focus ring.

### SUMMARY

The present disclosure provides a technique for suppressing occurrence of abnormal discharge between a semiconductive member and a conductive member.

In accordance with an aspect of the present disclosure, there is provided a plasma processing apparatus, including: a chamber having a plasma processing space; a stage disposed in the plasma processing space, the stage having an electrostatic chuck; a semiconductive ring disposed on the stage so as to surround a substrate placed on the stage, the semiconductive ring having a first face; a power source; at least one conductive member disposed in the stage, the conductive member being in electrical connection with the power source; and a conductive layer disposed on the first face of the semiconductive ring, the conductive layer being in electrical connection with the at least one conductive member.

### BRIEF DESCRIPTION OF THE DRAWINGS

The objects and features of the present disclosure will become apparent from the following description or embodiments, given in conjunction with the accompanying drawings, in which:

FIG. 1 schematically shows an example of a cross section of a plasma processing apparatus according to an embodiment;

FIG. 2 schematically shows a configuration of the plasma processing apparatus according to an embodiment;

FIG. 3 shows an example of a configuration of a stage according to an embodiment;

FIG. 4 schematically shows a configuration of a conventional conductive member;

FIGS. 5A to 5C schematically show a configuration of a conductive member according to an embodiment;

FIG. 6 shows temperature distribution of a focus ring due to changes in resistivity of a conductive layer;

FIG. 7A schematically shows a configuration of a conventional conductive member;

FIG. 7B shows an example of a result of a test of measuring a leakage amount of a heat transfer gas;

FIG. 8A schematically shows a configuration of a conductive member according to an embodiment;

FIG. 8B shows an example of a result of a test of measuring a leakage amount of a heat transfer gas;

FIG. 9A schematically shows the configuration of conductive member according to an embodiment; and

FIG. 9B shows an example of a result of a test of measuring a leakage amount of a heat transfer gas.

### DETAILED DESCRIPTION

Hereinafter, embodiments of a plasma processing apparatus, a semiconductive member, and an edge ring of the present disclosure will be described in detail with reference to the accompanying drawings. The plasma processing apparatus, the semiconductive member, and the edge ring are not limited by the present embodiments.

In a plasma processing apparatus, a semiconductive member made of a semiconductor material such as Si, SiC, or the like may be used. For example, in the plasma processing apparatus, a semiconductor material may be used for an edge ring such as a focus ring disposed around a substrate, an upper electrode, a GND member having a GND potential, a chamber wall, a baffle plate, or the like. When a power is supplied to the semiconductive member made of such a semiconductor material, abnormal discharge may occur between the semiconductive member and a conductive member for supplying a power to the semiconductive member.

Therefore, there is a demand for a technique for suppressing occurrence of abnormal discharge between the semiconductive member and the conductive member.

(Configuration of Plasma Processing Apparatus)

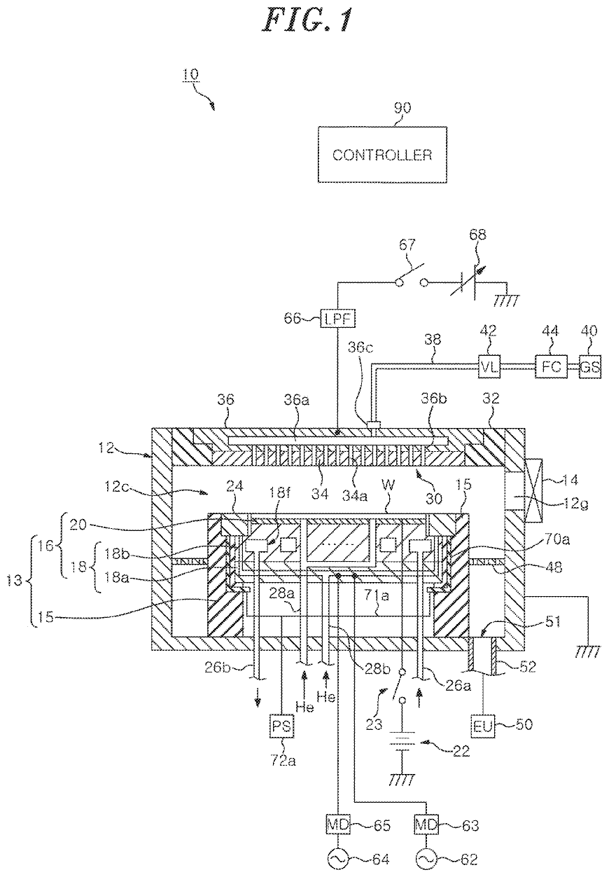

An example of a plasma processing apparatus according to an embodiment will be described. In the present embodiment, a case where the plasma processing apparatus performs plasma etching as plasma processing on a substrate will be described as an example. A wafer will be described as an example of the substrate. FIG. 1 schematically shows an example of a cross section of a plasma processing apparatus 10 according to an embodiment. The plasma processing apparatus 10 shown in FIG. 1 is a capacitively coupled plasma processing apparatus.

The plasma processing apparatus 10 includes an airtight chamber 12. The chamber 12 has a substantially cylindrical shape, is made of, e.g., aluminum or the like. The chamber 12 has an inner space serving as a plasma processing space 12c for performing plasma processing. A plasma resistant film is formed on an inner wall surface of the chamber 12. This film may be an alumite film or a film made of yttrium oxide. The chamber 12 is grounded. An opening 12g is formed on a sidewall of the chamber 12. The wafer W passes through the opening 12g when the wafer W is loaded into the plasma processing space 12c from the outside or when the wafer W is unloaded from the plasma processing space 12c to the outside. A gate valve 14 for opening/closing the opening 12g is provided on the sidewall of the chamber 12.

A support 13 for supporting the wafer W is disposed near the center of the inner space of the chamber 12. The support 13 includes a support member 15 and a stage 16. The support member 15 has a substantially cylindrical shape and is disposed on a bottom portion of the chamber 12. The support member 15 is made of, e.g., an insulating material. In the chamber 12, the support member 15 extends upward from the bottom portion of the chamber 12. The stage 16 is disposed in the plasma processing space 12c. The stage 16 is supported by the support member 15.

The stage 16 is configured to hold the wafer W placed thereon. The stage 16 includes a lower electrode 18 and an electrostatic chuck 20. The lower electrode 18 has a first plate 18a and a second plate 18b. The first plate 18a and the second plate 18b are made of a metal such as aluminum and have a substantially disc shape. The second plate 18b is disposed on the first plate 18a and is electrically connected to the first plate 18a.

The electrostatic chuck 20 is disposed on the second plate 18b. The electrostatic chuck 20 has an insulating layer and a film-shaped electrode embedded in the insulating layer. A DC power supply 22 is electrically connected to the electrode of the electrostatic chuck 20 through a switch 23. A DC voltage is applied from the DC power supply 22 to the electrode of the electrostatic chuck 20. When the DC voltage is applied to the electrode of the electrostatic chuck 20, the electrostatic chuck generates an electrostatic attractive force to attract and hold the wafer W on the electrostatic chuck 20. A heater may be disposed in the electrostatic chuck 20, and a heater power supply disposed outside the chamber 12 may be connected to the heater.

A semiconductive ring (focus ring) 24 is disposed on a peripheral portion of the second plate 18b. The semiconductive ring 24 is a substantially annular plate. The semiconductive ring 24 is disposed to surround the edge of the wafer W and the electrostatic chuck 20. The semiconductive ring 24 is provided to improve the uniformity of etching. The semiconductive ring 24 is made of a semiconductor material, e.g., silicon (Si) or a compound semiconductor such as GaAs, SiC, GaP, or the like. The semiconductive ring 24 has a diameter greater than that of the stage 16, and an outer edge of the semiconductive ring 24 is disposed on the support member 15.

The plasma processing apparatus 10 is configured to supply a power to the semiconductive ring 24. For example, the plasma processing apparatus 10 is configured to apply a DC voltage to the semiconductive ring 24 in order to attract the semiconductive ring 24 to the stage 16. A conductive member 70a is provided below the semiconductive ring 24 at the support member 15. The conductive member 70a is in contact with the semiconductive ring 24. The conductive member 70a is connected to a power source (PS) 72a by a wiring 71a. The power source 72a supplies a DC voltage to the semiconductive ring 24 in a pulsed manner. By applying the voltage to the semiconductive ring 24, an electric field on the semiconductive ring 24 may be changed and a thickness of a plasma sheath may be changed. Under the control of a controller 90 to be described later, the power source 72a supplies a DC voltage to the semiconductive ring 24 in a pulsed manner such that the thickness of the plasma sheath becomes substantially uniform above the wafer W and above the semiconductive ring 24.

A flow channel 18f is formed in the second plate 18b. A temperature control fluid is supplied from a chiller unit disposed outside the chamber 12 to the flow channel 18f through a line 26a. The temperature control fluid supplied to the flow path 18f is returned to the chiller unit through a pipe 26b. In other words, the temperature control fluid circulates between the flow path 18f and the chiller unit. By controlling the temperature of the temperature control fluid, a temperature of the stage 16 (or the electrostatic chuck 20) and a temperature of the wafer W are adjusted. The temperature control fluid may be, e.g., Galden®.

The plasma processing apparatus 10 further includes gas supply lines 28a and 28b. A heat transfer gas, e.g., He gas, from a heat transfer gas supply mechanism is supplied to the gas supply lines 28a and 28b. The gas supply line 28a communicates with through-holes formed near the center of the stage 16 and supplies the heat transfer gas to a gap between an upper surface of the electrostatic chuck 20 and a backside of the wafer W. The gas supply line 28b communicates with through-holes formed near the outer periphery of the stage 16 and supplies the heat transfer gas to a gap between an upper surface near the outer periphery of the stage 16 and a rear surface of the semiconductive ring 24.

The plasma processing apparatus 10 further includes a shower head 30. The shower head 30 is disposed above the stage 16. The shower head 30 is supported at an upper portion of the chamber 12 through an insulating member 32. The shower head 30 may include an electrode plate 34 and a holder 36. A bottom surface of the electrode plate 34 faces the plasma processing space 12c. The electrode plate 34 is provided with a plurality of gas injection holes 34a. The electrode plate 34 may be made of silicon or silicon oxide.

The holder 36 for detachably supporting the electrode plate 34 is made of an conductive material such as aluminum. Both of the electrode plate 34 and the holder 36 may be made of a semiconductor material.

A gas diffusion space 36a is formed in the holder 36. A plurality of gas holes 36b communicating with the gas injection holes 34a extends downward from the gas diffusion space 36a. The holder 36 has a gas inlet port 36c for guiding a gas to the gas diffusion space 36a. A gas supply line 38 is connected to the gas inlet port 36c.

A gas source group (GS) 40 is connected to the Gas supply line 38 through a valve group (VL) 42 and a flow controller group (FC) 44. The gas source group 40 includes gas sources of various gases used for plasma etching. The valve group 42 includes a plurality of valves. The flow controller group 44 includes a plurality of flow controllers such as mass flow controllers or pressure control type flow controllers. The gas sources of the gas source group 40 are connected to the gas supply line 38 through the corresponding valves of the valve group 42 and the corresponding flow controllers of the flow controller group 44. The gas source group 40 supplies various gases for plasma etching to the gas diffusion space 36a of the holder 36 through the gas supply line 38. The gas supplied to the gas diffusion space 36a is diffused and supplied in a shower-like manner into the chamber 12 through the gas holes 36b and the gas injection holes 34a.

A first radio frequency power source 62 is connected to the lower electrode 18 through a matching device (MD) 63. A second radio frequency power source 64 is connected to the lower electrode 18 through a matching device (MD) 65. The first radio frequency power source 62 generates a radio frequency power for plasma generation. The first radio frequency power source 62 supplies the radio frequency power having a predetermined frequency within a range of 27 MHz to 100 MHz, e.g., 40 MHz, to the lower electrode 18 of the stage 16 during plasma processing. The second radio frequency power source 64 generates a radio frequency power for ion attraction (for bias). The second radio frequency power source 64 supplies the radio frequency power having a predetermined frequency within a range of 400 kHz to 13.56 MHz, e.g., 3 MHz, which is lower than that of the first radio frequency power source 62, to the lower electrode 18 of the stage 16 during the plasma processing. In this manner, two radio frequency powers having different frequencies may be applied from the first radio frequency power source 62 and the second radio frequency power source 64 to the stage 16. The shower head 30 and the stage 16 function as a pair of electrodes (upper electrode and lower electrode).

A variable DC power supply (VDC) 68 is connected to the holder 36 of the shower head 30 through a low pass filter (LPF) 66. On/off of power supply from the variable DC power supply 68 can be controlled by an on/off switch 67. A current and a voltage of the variable DC power supply 68 and an on/off operation of the on/off switch 67 are controlled by the controller 90 to be described later. When plasma is generated in the processing space by applying the radio frequency power from the first radio frequency power source 62 and the second radio frequency power source 64 to the stage 16, the on/off switch 67 is turned on by the controller 90 and a predetermined DC voltage is applied to the holder 36, if necessary.

At the bottom portion of the chamber 12, a gas exhaust port 51 is disposed at a side portion of the support 13. An exhaust unit (EU) 50 is connected to the gas exhaust port 51 through a gas exhaust line 52. The exhaust unit 50 has a pressure controller such as a pressure control valve, and a vacuum pump such as a turbo molecular pump. The exhaust unit 50 can reduce a pressure in the chamber 12 to a desired level by exhausting the chamber 12 through the gas exhaust port 51 and the gas exhaust line 52.

In the chamber 12, a baffle plate 48 is disposed on an upstream side compared to the gas exhaust port 51 in a gas exhaust flow toward the gas exhaust port 51. The baffle plate 48 is disposed between the support 13 and the inner side surface of the chamber 12 to surround the support 13. The baffle plate 48 is, e.g., a plate-shaped member, and can be formed by coating ceramic such as Y₂O₃ on a surface of an aluminum base. The baffle plate 48 is a member having multiple slits, a mesh member, or a member having multiple punching holes, so that a gas can pass therethrough. The baffle plate 48 divides the inner space of the chamber 12 into the plasma processing space 12c for performing plasma processing on the wafer W and a gas exhaust space connected to a gas exhaust system for exhausting the chamber 12, such as the gas exhaust line 52, the gas exhaust unit 50, and the like.

The plasma processing apparatus 10 further includes the controller 90. The controller 90 is, e.g., a computer including a processor, a storage unit, an input device, display device, and the like. The controller 90 controls the respective components of the plasma processing apparatus 10. The controller 90 allows an operator to input a command input using the input device to manage the plasma processing apparatus 10. Further, the controller 90 allows the display device to visualize and display an operation status of the plasma processing apparatus 10. Further, the storage unit of the controller 90 stores recipe data and control programs for controlling various processes preformed in the plasma processing apparatus 10 by the processor. The processor of the controller 90 executes the control program and controls the respective components of the plasma processing apparatus 10 based on the recipe data, so that desired processing is performed by the plasma processing apparatus 10.

Here, as described above, in the plasma processing apparatus 10, a semiconductive member made of a semiconductor material may form at least a part of the chamber 12 or may be provided in the chamber 12. For example, in the plasma processing apparatus 10, a semiconductor material is used for the semiconductive ring 24 or the shower head 30 serving as the upper electrode. Further, in the plasma processing apparatus 10, semiconductor material may be used for at least a part of the chamber 12 or the baffle plate 48. Further, in the plasma processing apparatus 10, a GND member having a GND potential and made of a semiconductor material may be disposed in the chamber 12. When a power is supplied to the semiconductive member made of a semiconductor material, abnormal discharge occurs between the conductive member for supplying a power to the semiconductive member and the semiconductive member.

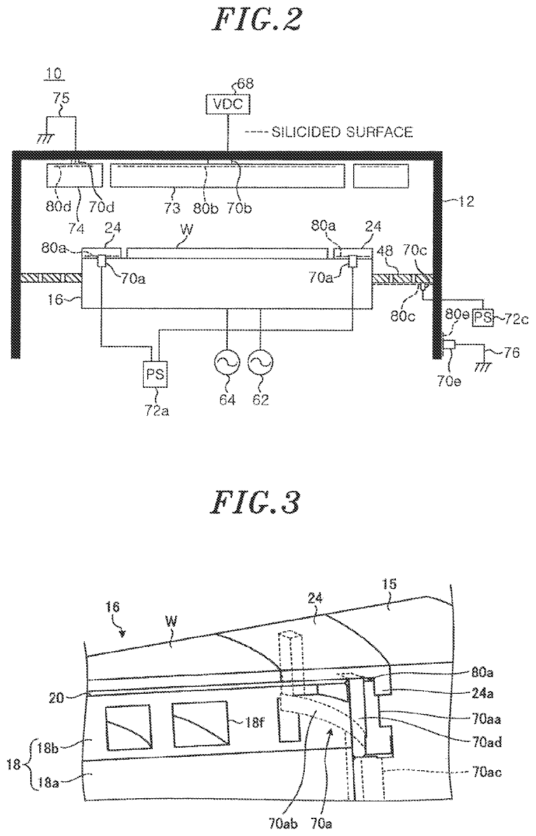

FIG. 2 schematically shows a configuration of the plasma processing apparatus 10 according to the embodiment. FIG. 2 shows the schematic configuration of the plasma processing apparatus 10. FIG. 2 shows the chamber 12. A stage 16 is disposed near the center of the inner space of the chamber 12. The wafer W is placed near the center of the stage 16, and the semiconductive ring 24 is arranged on the peripheral portion of the stage 16 to surround the periphery of the wafer W. The radio frequency power is supplied from the first radio frequency power source 62 and the second radio frequency power source 64 to the stage 16. The semiconductive ring 24 is made of a semiconductor material, e.g., silicon (Si) or a compound semiconductor such as GaAs, SiC, GaN, or the like. A DC power is supplied in a pulsed manner from the power source 72a to the semiconductive ring 24.

In the chamber 12, an upper electrode 73 is disposed above the stage 16. The upper electrode 73 is, e.g., the shower head 30 shown in FIG. 1. The upper electrode 73 is made of a semiconductor material. The variable DC power supply 68 is connected to the upper electrode 73, and supplies a power.

The baffle plate 48 is disposed around the stage 16. The baffle plate 48 is made of a semiconductor material. A power source (PS) 72c is connected to the baffle plate 48, and supplies a power in a pulsed manner or periodically.

Referring to FIG. 2, a GND member 74 is disposed around the upper electrode 73 in the chamber 12. The GND member 74 is made of a semiconductor material. The GND member 74 is grounded through a wiring 75 to have a GND potential.

The chamber 12 and the conductive member for supplying a power may be made of a conductive metal such as aluminum or the like. Aluminum has a specific resistance (or resistivity) on the order of 10e⁻⁶ Ω·cm. On the other hand, the semiconductive member has a higher resistivity than the conducive metal. For example, although Si is a semiconductor, its resistivity is reduced to about several Ω·cm by doping, and its resistivity is different from that of aluminum by about 6 orders of magnitude. The electrical contact between the semiconductor and the conductive metal is a non-ohmic junction, e.g., a pn junction, a Schottky barrier, a hetero junction with a rectifying action, or the like. At the contact portion, a resistance is high and an electric field is strong, which results in abnormal discharge such as electrical breakdown or the like.

Therefore, in the plasma processing apparatus 10 according to the embodiment, a conductive layer is provided at least on a contact surface between the semiconductive member and the conductive member for supplying a power to the semiconductive member or for setting the semiconductive member to a GND potential. The conductive layer may be disposed at least on the contact surface in contact with the conductive member. In other words, the conductive layer may be disposed only on the contact surface in contact with the conductive member, or may be disposed on the contact surface and a surface around the contact surface.

For example, the conductive layer is formed by performing a conversion process such that non-ohmic contact between the semiconductive member and the conductive member becomes ohmic contact. Such a conversion process may be sputtering, vapor deposition, plating, welding, or annealing using a conductive metal. The sputtering, the vapor deposition, the plating, the welding, and the annealing may be performed in combination. For example, the annealing may be performed after the sputtering, the vapor deposition, the plating, and the welding to further reduce a contact resistance.

The conductive metal used in the conversion process may include Al, Ni, Co, V, Ti, Zr, Hf, W and Au. For example, any one of the sputtering, the vapor deposition, the plating, the welding, and the annealing is performed on the contact surface between the semiconductive member and the conductive member using any one of the conductive metals Al, Ni, Co, V, Ti, Zr, Hf, W, and Au. The conversion process such as the sputtering, the vapor deposition, the plating, and the welding, or a part of the annealing performed after the conversion process may be performed in the chamber 12.

In the plasma processing apparatus 10, silicidation performed by the conversion process, so that a conductive layer is formed at least on the contact surface between the semiconductive member and the conductive member. For example, in the plasma processing apparatus 10 shown in FIG. 2, a conductive layer 80a is formed on a contact surface between the semiconductive ring 24 and the conductive member 70a for supplying a power from the power source 72a to the semiconductive ring 24. Further, in the plasma processing apparatus 10, a conductive layer 80b is formed on a contact surface between the variable DC power supply 68 and a conductive member 70b for supplying a power from the variable DC power supply 68 to the upper electrode 73. Further, in the plasma processing apparatus 10, a conductive layer 80c is formed on a contact surface between the baffle plate 48 and a conductive member 70c for supplying a power from the power source 72c to the baffle plate 48. Further, in the plasma processing apparatus 10, a conductive layer 80d is formed on a contact surface between the GND member 74 and a conductive member 70d that is an end portion of the ground wiring 75. Further, in the plasma processing apparatus 10, a conductive layer 80e is formed on a contact surface between the chamber 12 and a conductive member 70e that is an end portion of a ground wiring 76. In the plasma processing apparatus 10, besides forming the conductive layer by the conversion process of the member, a member made of Si ingot with an increased doping amount may be disposed as the conductive layer. For example, the conductive layers 80a to 80e may be members made of conductive Si ingot.

Therefore, the semiconductive member is in ohmic contact with the conductive member (metal) or an electrically grounded material (metal), and the resistance value is reduced. Further, even if a large radio frequency current flows, occurrence of abnormal heat generation or power loss is suppressed. Since the resistance is reduced, the potential difference is reduced and abnormal discharge is suppressed, which makes it possible to perform a stable process.

Next, an example of a specific configuration in which a conductive layer is provided at least on the contact surface between the semiconductive member and the conductive member will be described. Hereinafter, an example of a specific configuration in which the conductive layer 80a is provided on the contact surface between the conductive member 70a and the semiconductive ring 24 will be described.

FIG. 3 shows an example of the configuration of the stage 16 according to the embodiment. FIG. 3 shows an enlarged view of the vicinity of the periphery of the stage 16.

The stage 16 includes the lower electrode 16 and the electrostatic chuck. 20. The lower electrode 18 has the first plate 18a and the second plate 18b. The second plate 18b is disposed on the first plate 18a. The flow channel 181 is formed in the second plate 18b. The electrostatic chuck 20 is disposed on the second plate 18b. When a DC voltage is applied from the DC power source 22 to the electrode formed in the electrostatic chuck 20, the electrostatic chuck 20 generates an electrostatic attractive force to attract and hold the wafer W and the semiconductive ring 24. The electrostatic chuck 20 may have electrodes corresponding to the area of the wafer W and the area of the semiconductive ring 24, and a DC voltage may be applied from the DC power source 22 to each of the electrodes to individually hold the wafer W and the semiconductive ring 24. When the electrostatic chuck 20 have separate electrodes, multiple DC power sources 22 may be provided and individually connected to the electrodes the electrostatic chuck 20. Then, the multiple DC power sources 22 may individually apply a DC voltage to the respective electrodes of the electrostatic chuck 20 for the electrodes to individually hold the wafer W and the semiconductive ring 24.

The support member 15 made of an insulating material. is disposed around the stage 16. The wafer W is placed on the center of the stage 16, and the semiconductive ring 24 is disposed to surround the wafer W. The semiconductive ring 24 has a diameter greater than that of the stage 16, and an outer periphery of the semiconductive ring 24 is disposed on the support member 15. The semiconductive ring 24 has an annular protrusion 24a protruding downward from the peripheral bottom surface of the semiconductive ring 24. The annular protrusion 24a is formed in an annular shape along the circumferential periphery of the bottom surface of the semiconductive ring 24.

The conductive member 70a for supplying a power to the semiconductive ring 24 is disposed at the support member 15. The conductive member 70a has conductive pins 70aa, arc portions 70ab, and columnar portions 70ac. The conductive pins 70aa are disposed at intervals in the circumferential direction of the semiconductive ring 24. For example, the support member 15 is provided with through-holes formed at regular angles (e.g., 30°) in the circumferential direction of the semiconductive ring 24, and the conductive pins 70aa are disposed in the through-holes. In the through-holes, insulating members 70ad made of an insulating material are disposed on the stage 16 side of the conductive pins 70aa while the conductive pins 70aa being insulated from the stage 16. The upper surfaces of the conductive pins 70aa are not in contact with the semiconductive ring 24 due to spaces between the upper surfaces of the upper tip ends of the conductive pins 70a and the semiconductive ring 24, and the side surfaces of the tip ends of the conductive pins 70aa are in contact with the inner circumference of the annular protrusion 24a of the semiconductive ring 24.

The arc portion 70ab is formed in the support member 15 along the circumferential direction. The lower parts of the conductive pins 70aa are connected to the arc portion 70ab. The arc portion 70ab is connected to the columnar portion 70ac.

The columnar portion 70ac is connected to the power source 72a through the above-described wiring 71a, and a power is supplied from the power source 72a to the columnar portion 70ac. The power supplied from the power source 72a is supplied to the semiconductive ring 24 from the contact surface in contact with the side surface of the tip end of each conductive pin 70aa through the columnar portion 70ac, the arc portion 70ab, and the conductive pin 70aa. The conductive layer 80a is disposed on the contact surface between the tip end of the conductive pin 70aa and the semiconductive ring 24. For example, the conductive layer 80a as disposed on the inner peripheral surface of the annular protrusion 24a of the semiconductive ring 24 along the entire circumferential direction.

Therefore, the semiconductive ring 24 and the conductive member 70a are in ohmic contact, and the resistance is reduced. Further, even if a high radio frequency current flows, the occurrence of abnormal heat generation or power loss on the contact surface is suppressed. Since the resistance is reduced, the potential difference is reduced. Accordingly, it is possible to suppress abnormal discharge and to perform stable processing.

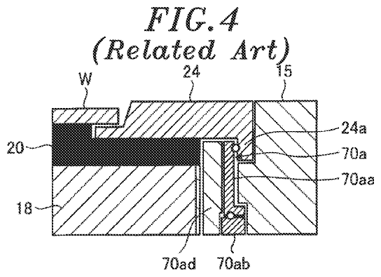

Next, a specific example of the effect of providing the conductive layer on the contact surface between the semiconductive member and the conductive member will be described. First, a configuration of a conventional conductive member having no conductive layer will be described. FIG. 4 schematically shows the configuration of a conventional conductive member. FIG. 4 schematically shows the configuration of the conductive member 70a for supplying a power to the semiconductive ring 24. In FIG. 4, the conductive layer 80a is not disposed on the contact surface between the semiconductive ring 24 and the conductive member 70a, and the semiconductive ring 24 and the conductive member 70a are in direct contact with each other. In this case, the electrical contact between the semiconductive ring 24 and the conductive member 70a is a non-ohmic contact, and the contact portion has a high resistance and a strong electric field, which results in abnormal discharge such as dielectric breakdown or the like. Further, a current is concentrated on the contact surface between the semiconductive ring 24 and the conductive member 70a, and the vicinity of the contact surface of the semiconductive ring 24 generates heat partially. When the semiconductive ring 24 generates heat partially, the semiconductive ring 24 is deformed by the heat.

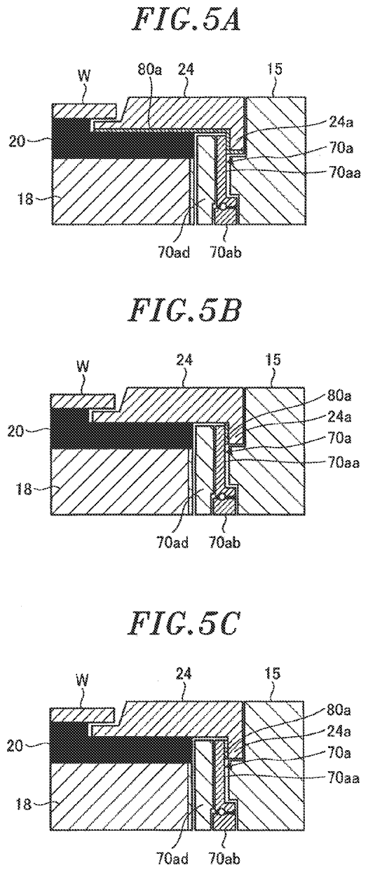

Therefore, in the plasma processing apparatus 10 according to the embodiment, the conductive layer 80a disposed at least on the contact surface between the semiconductive ring 24 and the conductive member 70a. FIGS. 5A to 5C schematically show the configuration of the conductive member of the present embodiment. FIGS. 5A to 5C schematically show the configuration of the conductive member 70a for supplying a power to the semiconductive ring 24. In FIG. 5A, the conductive layer 80a is disposed on the entire bottom surface including the contact surface between the semiconductive ring 24 and the conductive member 70a. In FIG. 5B, the conductive layer 80a is disposed on the entire inner peripheral surface of the annular protrusion 24a including the contact surface between the semiconductive ring 24 and the conductive member 70a. In FIG. 5C, the conductive layer 80a is disposed only on the contact surface between the annular protrusion 24a of the semiconductive ring 24 and the conductive member 70a. The entire semiconductive ring 24 may serve as the conductive layer 80a. For example, the semiconductive ring 24 may be made of a conductive metal so that the entire semiconductive ring 24 serves as the conductive layer 80a.

In order to suppress heat generation, the conductive layer 80a preferably has a resistivity of 0.02 Ω·cm or less.

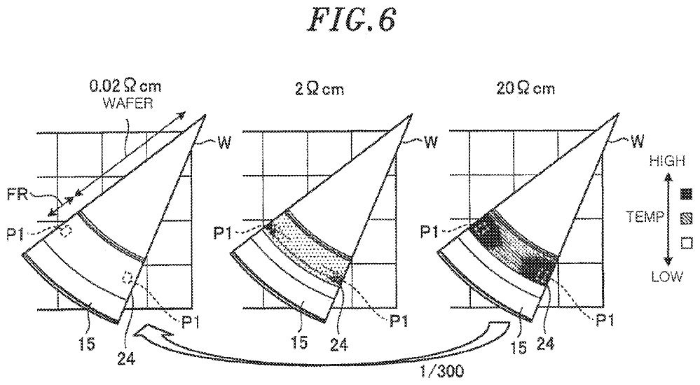

FIG. 6 shows variation in the temperature distribution of the semiconductive ring 24 due to changes in the resistivity of the conductive layer 80a. FIG. 6 shows positions P1 of the conductive pins 70aa of the conductive member 70a. In FIG. 6, the temperature distribution on the surface of the semiconductive ring 24 obtained in the case of setting the resistivity of the conductive layer 80a to 20 Ω·cm, 2 Ω·cm, and 0.02 Ω·cm are illustrated as patterns. The temperature of the semiconductive ring 24 is higher in a darker region. The amount of heat P generated at the electrical contact point between the semiconductive ring 24 and the conductive member 70a is calculated by the following equation (1) on the assumption that I indicates a current flowing through the conductive member 70a and R indicates a resistivity of the conductive layer 80a. The equation (1) is as follows:

P=R×I² (1).

When the resistivity of the conductive layer 80a is 20 Ω·cm and 2 Ω·cm, the current is insufficiently distributed and the current density near the positions P1 of the conductive pins 70aa where the semiconductive ring 24 and the conductive member 70a are in contact with each other increases, which results in local heat generation of the semiconductive ring 24. The semiconductive ring 24 is deformed due to the temperature distribution caused by the local heat generation. When the semiconductive ring 24 is deformed, it is difficult to stably attract the semiconductive ring 24 in the plasma processing apparatus 10. When it is difficult to stably attract the semiconductive ring 24 in the plasma processing apparatus 10, the leakage of the heat transfer gas (He gas) supplied to the rear side of the semiconductive ring 24 increases.

On the other hand, when the resistivity of the conductive layer 80a is 0.02 Ω·cm, the semiconductive ring 24 is not deformed because the current is sufficiently distributed and the temperature distribution becomes substantially uniform. Accordingly, it is possible to stably attract the semiconductive ring 24 in the plasma processing apparatus 10.

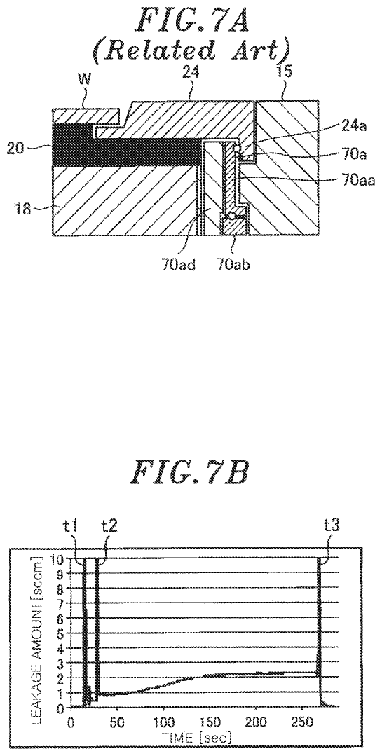

In this specification, the changes in the attraction characteristics of the semiconductive ring 24 will be described. FIG. 7A schematically shows the configuration of the conventional conductive member. FIG. 7A schematically shows the configuration of the conductive member 70a for supplying a power to the semiconductive ring 24. In FIG. 7A, the conductive layer 80a is not disposed on the contact surface between the semiconductive ring 24 and the conductive member 70a, and the semiconductive ring 24 and the conductive member 70a are in direct contact with each other. In this case, the resistivity of the electrical contact between the semiconductive ring 24 and the conductive member 70a is 1 Ω·cm to 2 Ω·cm. FIG. 7B shows an example of a result of a test of measuring the leakage amount of the heat transfer gas. FIG. 7B shows temporal changes of the leakage amount of the heat transfer gas (He gas) supplied to the rear surface of the semiconductive ring 24 in the case of employing the configuration of FIG. 7A. The pulse-shaped change in the leakage amount shown at timing t1 to t3 in FIG. 7B is a temporary change caused by start and end of the supply of the heat transfer gas. FIG. 7B shows that the leakage amount increases as time elapses. The increase in the leakage amount considered to be caused by the deformation of the semiconductive ring 24 due to the local heating of the semiconductive ring 24 as described above.

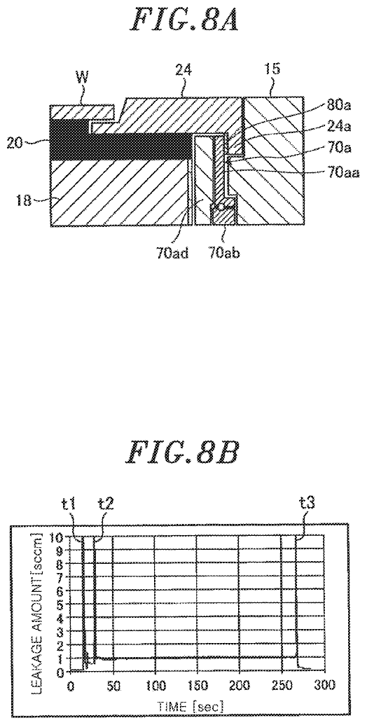

FIG. 8A schematically shows the configuration of the conductive member of the present embodiment. In FIG. 8A, the conductive layer 80a is disposed on the entire inner peripheral surface of the annular protrusion 24a including the contact surface between the semiconductive ring 24 and the conductive member 70a. FIG. 8B shows an example of a result of a test of measuring the leakage amount of the heat transfer gas. FIG. 8B shows temporal changes of the leakage amount of the heat transfer gas (He gas) supplied to the rear surface of the semiconductive ring 24 in the case of employing the configuration of FIG. 8A. The pulse-shaped change in the leakage amount shown at timing t1 to t3 in FIG. 8B is a temporary change caused by the start and the end of the supply of the heat transfer gas. In FIG. 8B, the leakage amount is not increased even after time elapses. This indicates that the semiconductive ring 24 is stably attracted even after the time elapses.

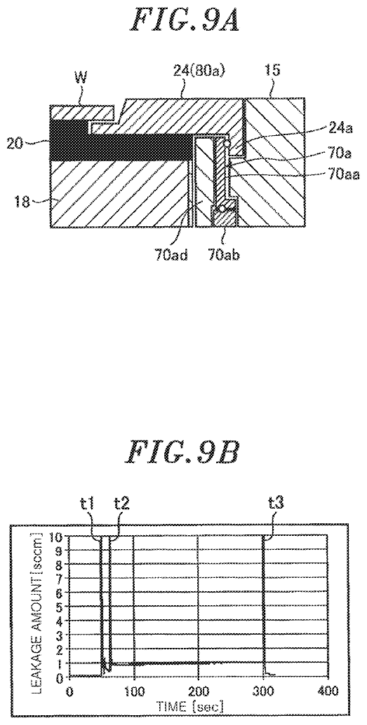

FIG. 9A schematically shows the configuration of the conductive member of the present embodiment. FIG. 9A shows the case in which the semiconductive ring 24 is made of a conductive metal having a resistivity of 0.02 Ω·cm and the entire semiconductive ring 24 serves as the conductive layer 80a. FIG. 9B shows an example of a result of a test of measuring the leakage amount of the heat transfer gas. FIG. 9B shows temporal changes of the leakage amount of the heat transfer as (He gas) supplied to the rear surface of the semiconductive ring 24 in the case of employing the configuration of FIG. 9A. The pulse-shaped change in the leakage amount shown at timing t1 to t3 in FIG. 9B is a temporary change caused by the start and the end of the supply of the heat transfer gas. In FIG. 9B, the leakage amount is not increased even after time elapses, which indicates that the semiconductive ring 24 is stably attracted even after the time elapses.

As described above, the plasma processing apparatus 10 according to the present embodiment includes the semiconductive member (e.g., the semiconductive ring 24, the upper electrode 73 (the shower head 30), the baffle plate 48, the GND member 74, the chamber 12) and the conductive member (e.g., the conductive members 70a to 70e). The semiconductive member made of a semiconductor material constitutes at least a part of the chamber 12 where the plasma processing is performed, or is disposed in the chamber 12. The conductive member supplies a power to the semiconductive member or sets the semiconductive member to a GND potential. The plasma processing apparatus 10 further includes a conductive layer (e.g., the conductive layers 80a to 80e) disposed at least on the contact surface between the semiconductive member and the conductive member. Accordingly, the plasma processing apparatus 10 can suppress occurrence of abnormal discharge between the semiconductive member and the conductive member

In the plasma processing apparatus 10 according to the present embodiment, the semiconductive member is any one or the edge ring (e.g., the semiconductive ring 24) that is disposed on the stage 16 for supporting the substrate in the chamber 12 to surround the periphery of the substrate, the upper electrode 73, the GND member 74 having the GND potential, the wall of the chamber 12, and the baffle plate 48. Accordingly, the plasma processing apparatus 10 can suppress occurrence of abnormal discharge between the conductive members 70a to 70e and the edge ring, the upper electrode 73, the GND member 74 having the GND potential, the wall of the chamber 12, and the baffle plate 48.

Further, in the plasma processing apparatus 10 according to the present embodiment, the conductive layer is formed by performing a predetermined conversion process such that non-ohmic contact at the contact surface with the conductive member becomes ohmic contact. Accordingly, the plasma processing apparatus 10 can suppress occurrence of abnormal discharge between the semiconductive member and the conductive member.

The conversion process is any of sputtering, vapor deposition, plating, welding, and annealing using a conductive metal. The conductive metal is any of Al, Ni, Co, V, Ti, Zr, Hf, W, and Au. Accordingly, the plasma processing apparatus 10 can suppress occurrence of abnormal discharge between the semiconductive member and the conductive member.

In the plasma processing apparatus 10 according to the present embodiment, the semiconductive member is the edge ring (e.g., the semiconductive ring 24) disposed on the stage 16 supporting the substrate in the chamber 12 to surround the periphery of the substrate. The conductive members 70a are disposed at the stage 16 at intervals in the circumferential direction of the edge ring while being in contact with the edge ring. The conductive layer 80a is formed on the contact surface between the surface of the edge ring on the stage 16 side and the conductive member 70a along the entire circumferential direction. Accordingly, in the plasma processing apparatus 10, the current is diffused to the conductive layer 80a, which makes it possible to suppress the local heat generation of the edge ring and the deformation of the edge ring.

In the plasma processing apparatus 10, the conductive layer 80a is formed on the entire surface of the edge ring on the stage 16 side. Therefore, in the plasma processing apparatus 10, the current is diffused to the entire surface of the edge ring on the stage 16 side. Accordingly, the temperature distribution of the edge ring can become substantially uniform and the deformation of the edge ring can be suppressed.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

In the above-described embodiments, the case where the plasma processing apparatus 10 is a capacitively coupled plasma processing apparatus has been described as an example. However, the present disclosure is not limited thereto, and any plasma processing apparatus may be employed. For example, the plasma processing apparatus 10 may be any type of plasma processing apparatus, such as an inductively coupled plasma processing apparatus or a plasma processing apparatus for exciting a gas with a surface wave such as a microwave.

In the above-described embodiments, the case where the first radio frequency power source 62 and the second radio frequency power source 64 are connected to the lower electrode 18 has been described as an example. However, the configuration of the plasma source is not limited thereto. For example, the first high frequency power source 62 for plasma generation may be connected to the shower head 30. Further, the second high frequency power source 64 for ion attraction (for bias) is not necessarily connected to the lower electrode 18.

The above-described plasma processing apparatus 10 is a plasma processing apparatus for performing etching as plasma processing. However, a plasma processing apparatus for performing any plasma processing may be employed. For example, the plasma processing apparatus 10 may be a single-wafer deposition apparatus for performing chemical vapor deposition (CVD), atomic layer deposition (ALD), physical vapor deposition (PVD), or the like, or may be a plasma processing apparatus for performing plasma annealing, plasma implantation, or the like.

In the above-described embodiments, the case where the substrate is a semiconductor wafer has been described as an example. However, the present disclosure is not limited thereto, and the substrate, may be another substrate such as a glass substrate or like.

1. A plasma processing apparatus, comprising:
a chamber having a plasma processing space;
a stage disposed in the plasma processing space, the stage having an electrostatic chuck; a semiconductive ring disposed on the stage so as to surround a substrate placed on the stage, the semiconductive ring having a first face;
a power source;
at least one conductive member disposed in the stage, the conductive member being in electrical connection with the power source; and
a conductive layer disposed on the first face of the semiconductive ring, the conductive layer being in electrical connection with the at least one conductive member.

2. The plasma processing apparatus according to claim 1, wherein the conductive layer is in ohmic contact with the semiconductive ring.

3. The plasma processing apparatus according to claim 2, wherein the ohmic contact is formed by any one of sputtering, vapor deposition, plating, welding, and annealing of a conductive metal.

4. The plasma processing apparatus according to claim 3, wherein the conductive metal is any one of Al, Ni, Co, V, Ti, Zr, Hf, W, and Au.

5. The plasma processing apparatus according to claim 4, wherein the semiconductive ring has a bottom face and an annular protrusion extending downwardly from the bottom face, and the annular protrusion has an inner side as the first face.

6. The plasma processing apparatus according to claim 5, wherein the at least one conductive member comprises a single conductive ring in contact with the semiconductive ring, and
the conductive layer extends over the entire inner side of the annular protrusion.

7. The plasma processing apparatus according to claim 5, wherein the at least one conductive member comprises a plurality of discrete conductive members in contact with the semiconductive ring, and
the conductive layer extends on the entire inner side of the annular protrusion.

8. The plasma processing apparatus according to claim 7, wherein the conductive layer further extends under the entire bottom face of the semiconductive ring.

9. A plasma processing apparatus comprising:
a chamber having a plasma processing space;
a semiconductive member having a first face exposed to the plasma processing space and a second face opposite to the first face;
a conductive layer disposed on the second face of the semiconductive member;
a power source; and
a conductive member electrically connected to the power source and in contact with the conductive layer.

10. The plasma processing apparatus according to claim 9, wherein the conductive layer is in ohmic contact with the semiconductive member.

11. The plasma processing apparatus according to claim 10, wherein the ohmic contact is formed by any one of sputtering, vapor deposition, plating, welding, and annealing of a conductive metal.

12. The plasma processing apparatus according to claim 11, wherein the conductive metal is any one of Al, Ni, Co, V, Ti, Zr, Hf, W, and Au.

13. A plasma processing apparatus comprising:
a chamber having a plasma processing space;
a semiconductive member being at least part of the chamber and having a first face exposed to the plasma processing space and a second face opposite to the first face;
a conductive layer disposed on the second face of the semiconductive member; and
a conductive member in contact with the conductive layer, the conductive member being grounded.
